(19) United States
(12) Patent Application Publication
(10) Pub. No.: US 2025/0381641 A1
(43) Pub. Date: Dec. 18, 2025

(54) POLISHING APPARATUS AND SUBSTRATE POLISHING METHOD

(71) Applicant: Tokyo Electron Limited, Tokyo (JP)

(72) Inventors: Shinichi TANABE, Tokyo (JP); Naoki UMESHITA, Tokyo (JP); Toshikazu AKIMOTO, Tokyo (JP); Hiroyuki OMIYA, Tokyo (JP)

(73) Assignee: Tokyo Electron Limited, Tokyo (JP)

(21) Appl. No.: 19/303,470

(22) Filed: Aug. 19, 2025

Related U.S. Application Data
(63) Continuation of application No. PCT/JP2024/003948, filed on Feb. 6, 2024.

(30) Foreign Application Priority Data
Feb. 20, 2023 (JP) 2023-023983

(51) Int. Cl. B24B 37/30; H01L 21/306

(52) U.S. Cl. CPC B24B 37/30; H01L 21/30625

(57) ABSTRACT

A polishing apparatus includes: a processing container that is configured to provide a processing space in a vacuum atmosphere; a substrate holding unit that is configured to be disposed in the processing container and hold a substrate to be processed; a pad holding unit that is configured to be disposed to face the substrate holding unit and hold a pad; a slurry supply unit that is configured to supply a slurry which is an ionic liquid to a surface of the substrate or the pad; and a pressurizing head unit that is configured to pressurize the substrate holding unit or the pad holding unit, wherein one of the substrate holding unit and the pad holding unit is pressurized such that the substrate and the pad are in contact with each other, and the substrate and the pad are respectively rotated in a state where the slurry is supplied.

### CROSS-REFERENCE TO RELATED APPLICATIONS

This application is a continuation of International Application No. PCT/JP2024/003948, filed on Feb. 6, 2024 which claims the benefit of priority of the prior Japanese Patent Application No. 2023-023983, filed on Feb. 20, 2023, the entire contents of each are incorporated herein by reference.

### FIELD

The present disclosure relates to a polishing apparatus and a substrate polishing method.

### BACKGROUND

It is disclosed that a polishing apparatus for a semiconductor wafer includes a polishing table for holding a polishing cloth, a wafer holding unit for holding a wafer to be polished, and a polishing end point detection unit in the polishing table, and includes a unit for measuring a slurry temperature during polishing in the end point detection unit (JP 2004-363229 A).

The present disclosure provides a polishing apparatus and a substrate polishing method capable of suppressing unintended oxidation of a substrate surface after polishing.

### SUMMARY

According to an aspect of a present disclosure, a polishing apparatus includes: a processing container that is configured to provide a processing space in a vacuum atmosphere; a substrate holding unit that is configured to be disposed in the processing container and hold a substrate to be processed; a pad holding unit that is configured to be disposed to face the substrate holding unit and hold a pad for polishing the substrate; a slurry supply unit that is configured to supply a slurry which is an ionic liquid to a surface of the substrate or the pad; and a pressurizing head unit that is configured to pressurize the substrate holding unit or the pad holding unit, wherein one of the substrate holding unit and the pad holding unit is pressurized such that the substrate and the pad are in contact with each other, and the substrate and the pad are relatively rotated in a state where the slurry is supplied.

### BRIEF DESCRIPTION OF DRAWINGS

FIG. 1 is a transverse sectional view illustrating an example of a substrate processing apparatus according to a first embodiment of the present disclosure;

FIG. 2 is a schematic sectional view illustrating an example of a polishing apparatus according to the first embodiment;

FIG. 3 is a view illustrating an example of a state of a substrate in a polishing step according to the first embodiment;

FIG. 4 is a flowchart illustrating an example of a substrate polishing method according to the first embodiment; and

FIG. 5 is a schematic sectional view illustrating an example of a polishing apparatus according to a second embodiment.

### DESCRIPTION OF EMBODIMENTS

Hereinafter, embodiments of the disclosed polishing apparatus and substrate polishing method will be described in detail with reference to the drawings. Note that the disclosed technology is not limited by the following embodiments.

Conventionally, in a step of planarizing a metal such as copper formed on a substrate, chemical mechanical polishing (CMP) is performed in the atmosphere. In CMP performed in the atmosphere, abrasive grains are dispersed in an aqueous solution, or a slurry (polishing liquid) to which an oxidizing agent is added is used. However, since these steps are performed in the atmosphere, an oxide film is formed on the metal surface after polishing. Therefore, it is necessary to remove the oxide film in a subsequent step. In order to solve these problems, an object of the present invention is to suppress unintentional oxidation of a substrate surface after CMP by performing CMP in a vacuum atmosphere. However, when CMP is performed using a slurry similar to that in the atmosphere in a vacuum atmosphere, a solvent such as water volatilizes from the slurry, and thus, friction more than expected occurs, and a polishing rate becomes excessive, or a cooling effect by the slurry cannot be obtained, etc., and therefore, appropriate polishing becomes difficult.

### First Embodiment

### Configuration of Substrate Processing Apparatus 1

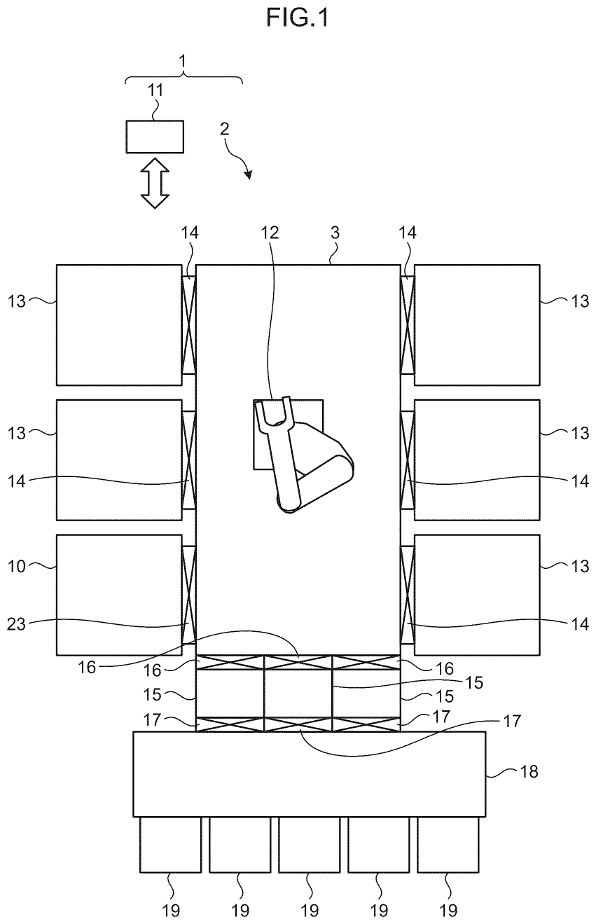

FIG. 1 is a transverse sectional view illustrating an example of a substrate processing apparatus according to a first embodiment of the present disclosure. A substrate processing apparatus 1 illustrated in FIG. 1 is capable of performing various types of processing such as polishing processing and plasma processing on a substrate (for example, a semiconductor wafer) on a single-wafer basis.

The substrate processing apparatus 1 includes an apparatus main body 2 and a control device 11 that controls the apparatus main body 2. As illustrated in FIG. 1, for example, the apparatus main body 2 includes a vacuum transfer chamber 3, a polishing apparatus 10, a plurality of process modules 13, a plurality of load lock modules 15, and an equipment front end module (EFEM) 18. In the following description, the vacuum transfer chamber 3 is also referred to as vacuum transfer module (VTM) 3, the process module 13 is also referred to as process module (PM) 13, and the load lock module 15 is also referred to as load lock module (LLM) 15.

The VTM 3 has a substantially quadrangular shape in plan view. In the VTM 3, the polishing apparatus 10 and the plurality of PMs 13 are connected to two opposing side surfaces. In addition, of another two opposing side surfaces of the VTM 3, the LLM 15 is connected to one of the side surfaces. The VTM 3 has a vacuum chamber, and a robot arm 12 is disposed therein.

The robot arm 12 is configured to be turnable, extendable, and liftable. The robot arm 12 can transfer the substrate among the polishing apparatus 10, the PM 13, and the LLM 15 by placing the substrate on a fork disposed at the leading end of the robot arm 12. The robot arm 12 is an example of a vacuum transfer robot. Note that the robot arm 12 is not limited to the configuration illustrated in FIG. 1 as long as it can transfer the substrate among the polishing apparatus 10, the PM 13, and the LLM 15.

The polishing apparatus 10 includes a processing chamber and a substrate holding unit disposed therein. After the substrate is held by the substrate holding unit, the polishing apparatus 10 supplies slurry in vacuum and performs polishing processing on the substrate by a pad. The VTM 3 and the polishing apparatus 10 are partitioned by a gate valve 23 which is openable and closable. Note that details of the configuration of the polishing apparatus 10 will be described later.

The PM 13 has a processing chamber and has a columnar stage (placing pedestal) disposed therein. After the substrate is placed on the stage, the PM 13 introduces a processing gas in a state where the inside of the processing chamber is depressurized, further applies high-frequency power to the inside of the processing chamber to generate plasma, and performs plasma processing on the substrate by the plasma. The VTM 3 and the PM 13 are partitioned by a gate valve 14 which is openable and closable. That is, since the substrate polished by the polishing apparatus 10 is conveyed to the PM 13 via the VTM 3 in a vacuum atmosphere, the substrate can be conveyed to the PM 13 in a state where unintended oxidation of the substrate surface after polishing is suppressed.

The LLM 15 is disposed between the VTM 3 and the EFEM 18. The LLM 15 includes an internal pressure-variable chamber whose internal pressure can be switched between vacuum and atmospheric pressure, and includes a cylindrical stage disposed inside the internal pressure-variable chamber. When the substrate is transferred into the VTM 3 from the EFEM 18, the LLM 15 maintains the inside of the internal pressure-variable chamber at atmospheric pressure to receive the substrate from the EFEM 18, and then decompresses the inside of the internal pressure-variable chamber to transfer the substrate into the VTM 3. In addition, when the substrate is transferred out from the VTM 3 to the EFEM 18, the LLM 15 maintains the inside of the internal pressure-variable chamber at vacuum to receive the substrate from the VTM 3, and then increases the pressure inside the internal pressure-variable chamber to atmospheric pressure to transfer the substrate out to the EFEM 18. The LLM 15 and the VTM 3 are partitioned by a gate valve 16 which is openable and closable. The LLM 15 and the EFEM 18 are partitioned by a gate valve 17 which is openable and closable.

The EFEM 18 is disposed opposite to the VTM 3. The EFEM 18 has a rectangular parallelepiped shape, and is an air transport chamber which includes a fan filter unit (FFU) and is held in an atmospheric-pressure environment. Three LLMs 15 are connected to one side surface in the longitudinal direction of the EFEM 18. 5 load ports (LP) 19 are connected to another side surface in the longitudinal direction of the EFEM 18. A FOUP (Front-Opening Unified Pod) (not illustrated), which is a container for accommodating a plurality of substrates, is placed on the LP19. An atmospheric transfer robot (robot arm) that transfers a substrate is disposed in the EFEM 18 (not illustrated). The EFEM 18 is an example of a loader module.

The control device 11 includes a memory, a processor, and an input/output interface. The memory stores a program to be executed by the processor, and a recipe including, for example, conditions of each process. The processor executes the program read from the memory, and controls each unit of the substrate processing apparatus 1 via the input/output interface based on the recipe stored in the memory.

It should be noted that the LLM 15, as both an LLM and a polishing apparatus, may be equipped with functions and facilities equivalent to those of the polishing apparatus 10, thereby allowing a new PM 13 to be installed at the location of the polishing apparatus 10 illustrated in FIG. 1. In addition, a new PM 13 may be installed at the location of the polishing apparatus 10 in FIG. 1 by installing the polishing apparatus 10 adjacent to the EFEM 18 in an inert atmosphere at atmospheric pressure, performing predetermined polishing by the polishing apparatus 10, and then transferring the substrate to the LLM 15 via the EFEM 18 in the inert atmosphere at atmospheric pressure. At this time, substrate conveyance between the polishing apparatus 10 and the EFEM 18 uses a robot arm in the EFEM 18.

### Configuration of Polishing Apparatus 10

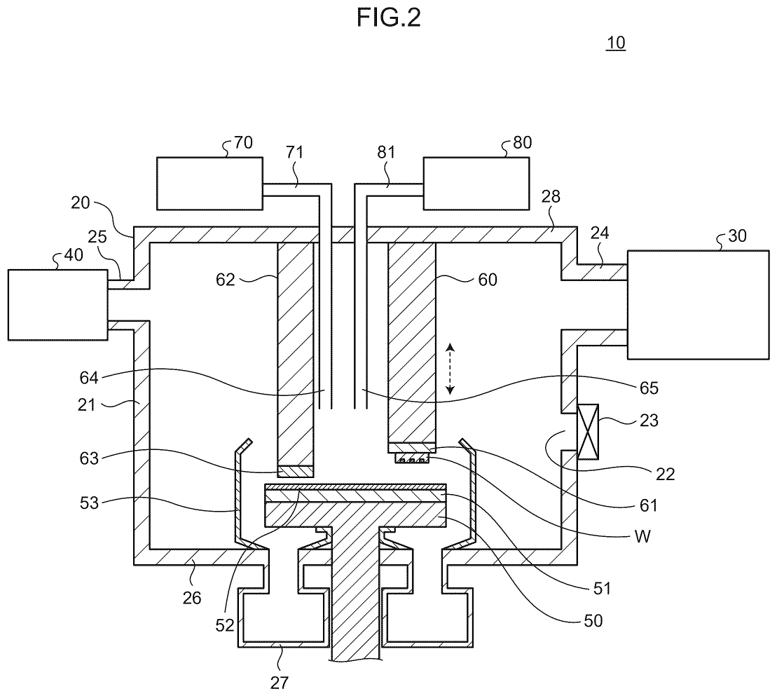

FIG. 2 is a schematic sectional view illustrating an example of the polishing apparatus according to the first embodiment. The polishing apparatus 10 illustrated in FIG. 2 is configured as, for example, a polishing apparatus using a face down mechanism.

The polishing apparatus 10 includes a chamber 20, an exhaust mechanism 30, a quadrupole mass spectrometer (QMS) 40, a rotation stage 50, a pressurizing head unit 60, a slurry supply unit 70, and a cleaning liquid supply unit 80.

An opening 22 through which a substrate W passes is formed in a side wall 21 of the chamber 20, and the opening 22 is opened and closed by the gate valve 23. The exhaust mechanism 30 is connected to an upper portion of the side wall 21 via an exhaust port 24. Furthermore, the quadrupole mass spectrometer 40 is connected to the upper portion of the side wall 21 via a pipe 25. The rotation stage 50 is disposed substantially at the center of a bottom surface 26 of the chamber 20. In addition, a recovery tank 27 for recovering the slurry is connected to the periphery of the rotation stage 50 on the bottom surface 26.

The pressurizing head unit 60, a pad dressing unit 62, and pipes 64, 65 are provided on the inner side of an upper surface 28 of the chamber 20. The slurry supply unit 70 and the cleaning liquid supply unit 80 are disposed on the outer side of the upper surface 28 of the chamber 20. The chamber 20 is an example of a processing container.

The exhaust mechanism 30 is provided with a vacuum pump and a pressure control valve. In one embodiment, the exhaust mechanism 30 is configured to adjust the pressure in the chamber 20 by controlling the vacuum pump and the pressure control valve. As the vacuum pump, for example, a dry pump, a turbo molecular pump, or the like can be used.

The quadrupole mass spectrometer 40 measures a partial pressure change of a degassing component, which is from an ionic liquid constituting the slurry supplied from the slurry supply unit 70 or a polished product of the substrate W. The quadrupole mass spectrometer 40 outputs the measurement value to the control device 11. The measurement value of the quadrupole mass spectrometer 40 is used for detecting a processing end point of the substrate W.

The rotation stage 50 includes a holding unit 51 that holds a pad and a pad 52. The holding unit 51 is disposed to face a substrate holding unit 61 that is provided at the leading end of the pressurizing head unit 60 and holds the substrate W to be processed. The pad 52 is for polishing the substrate W. The pad 52 may be made of, for example, foamed urethane, nonwoven fabric composed of polyester fibers and urethane, suede, acrylic, Al₂O₃, or the like. As the pad 52, a fixed abrasive pad in which abrasive grains are embedded in the pad, or a semi-fixed abrasive pad in which abrasive grains are embedded in a mesh-like resin may be used. The rotation stage 50 can polish the substrate W to be processed by CMP, for example, by rotating at 10 rpm to 300 rpm. A recovery cup 53 for recovering slurry is provided around the rotation stage 50. The recovery cup 53 has an upper portion inclined toward the rotation stage 50, and suppresses the rebound of the slurry and the cleaning liquid. Note that the recovery cup 53 is movable in the vertical direction by a drive mechanism, and when the substrate W is transferred in and out, the substrate W can be transferred in and out from the opening 22 by being moved in the downward direction.

The pressurizing head unit 60 includes the substrate holding unit 61 at the lower leading end. The substrate holding unit 61 holds the substrate W such that a surface to be polished of the substrate W to be processed faces the rotation stage 50. The substrate holding unit 61 holds the substrate W, for example, by an electrostatic chuck, a mechanical chuck, or the surface tension of an ionic liquid contained in a backing material such as foamed urethane wetted with the ionic liquid. The pressurizing head unit 60 is movable in the vertical direction, and presses the substrate W held by the substrate holding unit 61 against the pad 52 of the rotation stage 50, and for example, the rotation stage 50 and the pressurizing head unit 60 rotate at 10 rpm to 300 rpm, whereby the substrate W to be processed can be polished by CMP. That is, the holding unit 51 is disposed such that the surface of the pad 52 is the upper surface, the substrate holding unit 61 is configured to hold the substrate W such that the surface to be polished of the substrate W is the lower surface, and the substrate W is polished through pressurizing the substrate holding unit 61 downward by the pressurizing head unit 60. It should be noted that FIG. 2 illustrates a state in which both a metal film and a dielectric film such as an oxide are simultaneously exposed on the surface of the substrate W. However, only the metal film or only the dielectric film may be exposed on the surface.

The pad dressing unit 62 includes a grindstone 63 at the lower leading end. The pad dressing unit 62 is movable in the vertical direction, and presses the grindstone 63 against the pad 52 to scrape the surface of the pad 52 and refresh the surface of the pad 52.

The slurry supply unit 70 is connected to the pipe 64 penetrating the upper surface 28 of the chamber 20 via a pipe 71. The slurry supply unit 70 is provided with a plurality of ionic liquid tanks including a vacuum degassing mechanism for ionic liquid, a plurality of liquid feeding pumps, and a plurality of pH adjusting units. In one embodiment, the slurry supply unit 70 is configured to supply at least one kind of slurry from an ionic liquid tank including a vacuum degassing mechanism for ionic liquid into the chamber 20 via a corresponding liquid feeding pump and a corresponding pH adjusting unit. That is, in the chamber 20, a slurry which is an ionic liquid is dropped and supplied from the pipe 64 onto the pad 52.

Since the inside of the chamber 20 is in a vacuum atmosphere, the slurry supply unit 70 supplies the slurry to a leading end valve of the pipe 64 by a liquid feeding pump that applies a mechanical pressure such as a diaphragm type pump, a tubing type pump, or a capacity calculation type pump. The leading end valve is an example of a discharge unit. In the leading end valve of the pipe 64, a plunger mechanically performs suction and discharge of a fixed amount of slurry, whereby supplying the slurry from the leading end valve into the chamber 20. A needle valve type or a stop valve type may be used for opening and closing the leading end valve. Note that the leading end valve may include a syringe. In addition, the slurry supply unit 70 may supply the slurry by providing a slit instead of a valve at the leading end of the pipe 64. The supply amount of the slurry is measured by, for example, a flow volume sensor using ultrasonic waves provided in the pipe 71, a mass meter provided in the ionic liquid tank in the slurry supply unit 70, a mass meter provided in the rotation stage 50, or the like. The slurry recovered by the recovery cup 53 is stored in the recovery tank 27 using gravity. The slurry stored in the recovery tank 27 may be recovered and reused during intervals in the process, for example. The slurry stored in the recovery tank 27 may be circulated during a polishing step by, for example, a pump which is not illustrated and to which mechanical pressure can be applied.

The cleaning liquid supply unit 80 is connected to the pipe 65 penetrating the upper surface 28 of the chamber 20 via a pipe 81. The cleaning liquid supply unit 80 is provided with a plurality of ionic liquid tanks including a vacuum degassing mechanism for ionic liquid, a plurality of liquid feeding pumps, and a plurality of pH adjusting units. In one embodiment, the cleaning liquid supply unit 80 is configured to supply at least one kind of cleaning liquid from an ionic liquid tank including a vacuum degassing mechanism for ionic liquid into the chamber 20 via a corresponding liquid feeding pump. That is, in the chamber 20, a cleaning liquid which is an ionic liquid is dropped and supplied from the pipe 65 onto the pad 52.

Since the inside of the chamber 20 is in a vacuum atmosphere, the cleaning liquid supply unit 80 supplies the cleaning liquid to a leading end valve of the pipe 65 by a liquid feeding pump that applies a mechanical pressure such as a diaphragm type pump, a tubing type pump, or a capacity calculation type pump. In the leading end valve of the pipe 65, a plunger mechanically performs suction and discharge of a fixed amount of cleaning liquid, whereby supplying the cleaning liquid from the leading end valve into the chamber 20. A needle valve type or a stop valve type may be used for opening and closing the leading end valve. Note that the leading end valve may include a syringe. In addition, the cleaning liquid supply unit 80 may supply the cleaning liquid by providing a slit instead of a valve at the leading end of the pipe 65. The supply amount of the cleaning liquid is measured by, for example, a flow volume sensor using ultrasonic waves provided in the pipe 81, a mass meter provided in the ionic liquid tank in the cleaning liquid supply unit 80, a mass meter provided in the rotation stage 50, or the like. The cleaning liquid recovered by the recovery cup 53 is stored in a recovery tank 27 different from the recovery tank 27 storing the slurry. That is, a valve which is not illustrated is provided at the inlet of the recovery tank 27, and the valve is controlled to switch between slurry recovery and cleaning liquid recovery so that the slurry and the cleaning liquid are recovered in different recovery tanks 27. The cleaning liquid stored in the recovery tank 27 may be recovered and reused during intervals in the process, for example.

The control device 11 controls each unit of the polishing apparatus 10 so as to perform, for example, a substrate polishing method described later. As a detailed example, the control device 11 controls the polishing apparatus 10 to execute a step of holding the substrate W in the substrate holding unit 61 in the chamber 20. The control device 11 controls the polishing apparatus 10 to execute a step of operating the pressurizing head unit 60 in the vertical direction of the substrate W to apply pressure so that the substrate W and the pad 52 are in contact with each other, supplying the slurry, and rotating the substrate W and the pad 52 to polish the substrate W. The control device 11 controls the polishing apparatus 10 so as to execute a step of detecting the processing end point of the substrate W on the basis of a measurement value changed by polishing the substrate W. The control device 11 controls the polishing apparatus 10 to execute a step of supplying the cleaning liquid and removing the slurry and the cleaning liquid through spin drying by rotating the pressurizing head unit 60. The control device 11 controls the polishing apparatus 10 to execute a step of transferring out the substrate W held by the pressurizing head unit 60 from inside the chamber 20.

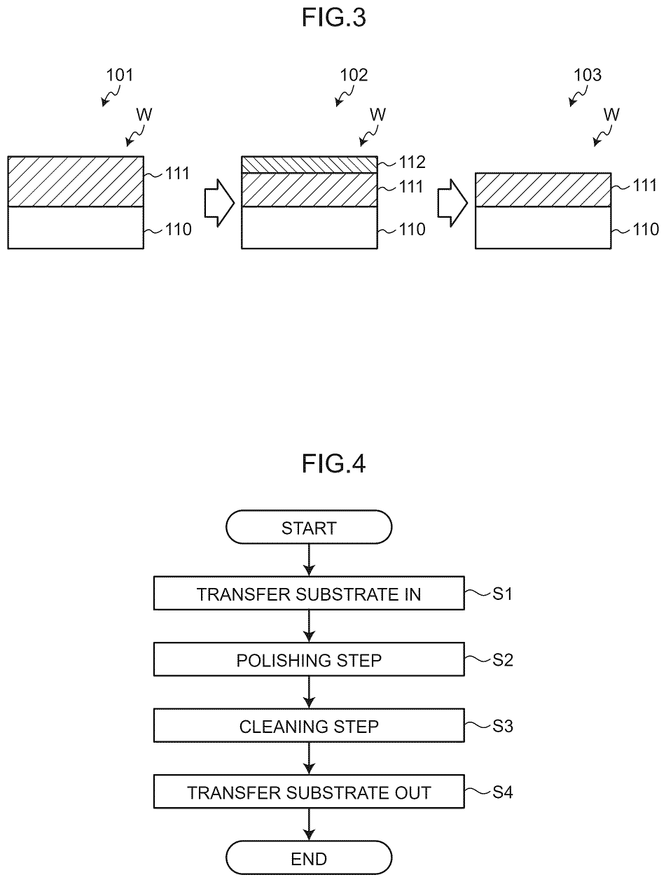

Next, the role of the slurry in the polishing step (CMP) will be described with reference to FIG. 3. FIG. 3 is a view illustrating an example of a state of the substrate in the polishing step according to the first embodiment. The substrate W in a state 101 illustrated in FIG. 3 is in a state in which a metal film 111 is formed on a silicon substrate 110. The state 101 is a state before the start of the polishing step, and by starting the polishing and supplying the slurry onto the substrate W, as illustrated in a state 102, a film 112 which is an oxide film or a complex film is formed on the metal film 111. At this time, the slurry serves as an oxidizing agent, a dispersant for abrasive grains, a coolant for the substrate W, and a lubricant between the substrate W and the pad 52. Thereafter, when mechanical polishing progresses due to the abrasive grains in the slurry or the pad, the pressurization of the substrate holding unit 61, and the rotation of the substrate W and the pad 52, the surface of the metal film 111 is planarized as illustrated in a state 103. In the state 103, a slurry serving as a corrosion inhibitor may be dropped on the surface of the metal film 111 after polishing. In the present embodiment, the ionic liquid used in the slurry also serves as a dispersant, and thus, a dispersant does not need to be separately added. It should be noted that, in the process of transitioning from the state 101 to the state 102, oxygen and moisture may be introduced into the chamber 20 under controlled conditions, and after the surface of the metal film 111 is converted into the film 112 which is an oxide film, the slurry may be supplied after the oxygen and moisture are removed by evacuation. At this time, the slurry serves as a coolant for the substrate W, a dispersant for abrasive grains, and a lubricant between the substrate W and the pad 52. Thereafter, when mechanical polishing progresses due to the abrasive grains in the slurry or the pad, the pressurization of the substrate holding unit 61, and the rotation of the substrate W and the pad 52, the surface of the metal film 111 is planarized as illustrated in a state 103.

### Ionic Liquid

Next, the ionic liquid used for the slurry supplied by the slurry supply unit 70 will be described. The ionic liquid used for the slurry is an ionic compound that is liquid at room temperature, and is changed according to the material to be polished on the substrate W. As the ionic liquid used for the slurry, for example, when the material to be polished is SiO₂, W, or Al, an acidic ionic liquid is used. Examples of the acidic ionic liquid include protic ionic liquids, ionic liquids having a sulfone group HSO₄− in an anion, ionic liquids having a sulfone group in a cation, and ionic liquids having sulfone groups in an anion and a cation.

Examples of the protic ionic liquid include ethylammonium nitrate represented by a chemical formula (D1). Examples of ionic liquids having the sulfone group HSO₄⁻ in the anion include 1-butyl-3-methylimidazolium hydrogen sulfate (Bmim-HSO₄) represented by a chemical formula (D2), and 1-ethyl-3-methylimidazolium hydrogen sulfate (Emim-HSO₄) represented by a chemical formula (D3).

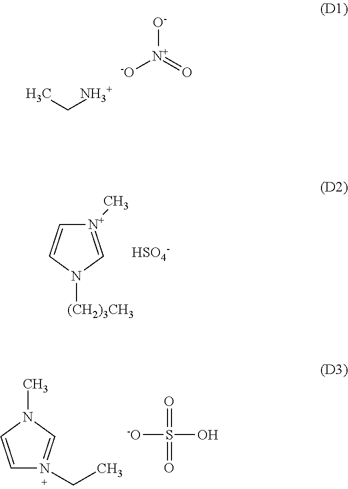

Examples of ionic liquids having a sulfone group in the cation include 1-(4-Sulfobutyl)-3-methylimidazolium bis(trifluoromethanesulfonyl)imide represented by a chemical formula (D4), and 1-(4-Sulfobutyl)-3-methylimidazolium trifluoromethanesulfonate represented by a chemical formula (D5).

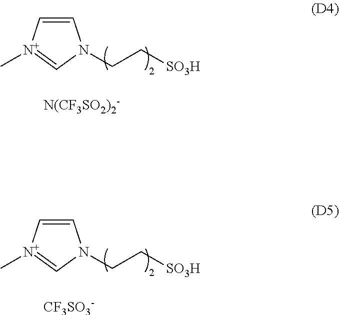

Examples of ionic liquids having sulfone groups in the anion and the cation include 1-(4-Sulfobutyl)-3-methylimidazolium hydrogen sulfate represented by a chemical formula (D6).

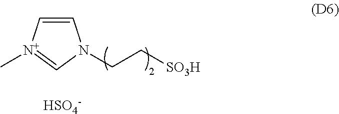

In addition, Emim-AlCl₄, Bmim-AlCl₄, or the like can be used as an acidic ionic liquid having AlCl₄⁻ in an anion. Furthermore, Hmim-Cl or the like can be used as an acidic ionic liquid having Cl⁻ in an anion.

As the ionic liquid used for the slurry, for example, when the material to be polished is SiOC, a basic ionic liquid is used. Examples of the basic ionic liquid include those in which the anion is acetate. Examples of the basic ionic liquid in which the anion is acetate include 1-ethyl-3-methylimidazolium acetate (Emim-AcO), and 1-butyl-3-methylimidazolium acetate (Bmim-AcO).

As the ionic liquid used for the slurry, for example, when the material to be polished is Cu, an ionic liquid that forms a Cu complex film is used. Examples of the ionic liquid that forms the Cu complex film include ionic liquids obtained by adding quinaldinic acid to the following various ionic liquids.

For various ionic liquids, examples of the cations constituting the ionic liquid include cations of a pyridinium type containing nitrogen, an imidazolium type, an ammonium type, a pyrrolidinium type, a piperidinium type, and a phosphonium type containing phosphorus. These cations each include an alkyl group —(CH₂)ₙCH₃ as a side chain.

Examples of cations of the pyridinium type include C₂py⁺ represented by a chemical formula (C1-1) and C₄py⁺ represented by a chemical formula (C1-2), but are not limited thereto.

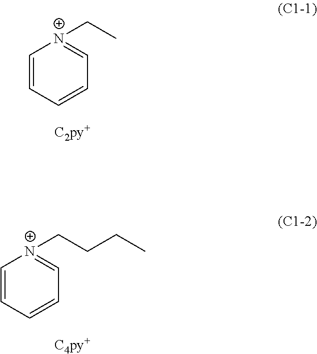

Examples of cations of the imidazolium type include C₂mim⁺ represented by a chemical formula (C2-1), C₄mim⁺ represented by a chemical formula (C2-2), C₆mim⁺ represented by a chemical formula (C2-3), and C₈mim⁺ represented by a chemical formula (C2-4), but are not limited thereto.

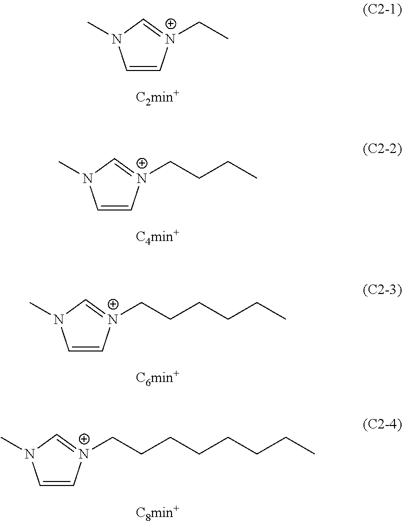

Examples of cations of the ammonium type include N_{3,1,1,1}⁺ represented by a chemical formula (C3-1), N_{4,1,1,1}⁺ represented by a chemical formula (C3-2), N_{6,1,1,1}⁺ represented by a chemical formula (C3-3), N_{2,2,1,(2O1)}⁺ represented by a chemical formula (C3-4), and Ch⁺ represented by a chemical formula (C3-5), but are not limited thereto.

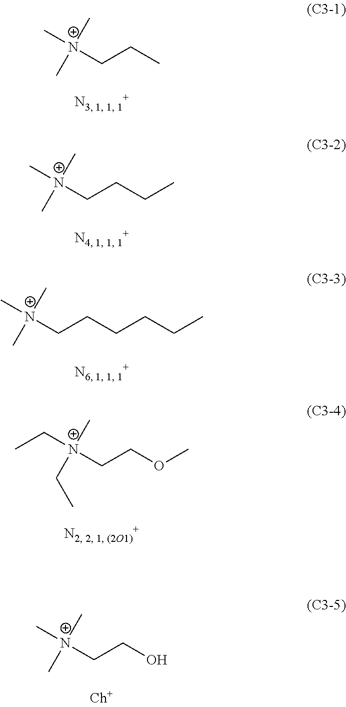

Examples of cations of the pyrrolidinium type include Pyr_{1,3}⁺ represented by a chemical formula (C4-1) and Pyr_{1,4}⁺ represented by a chemical formula (C4-2), but are not limited thereto.

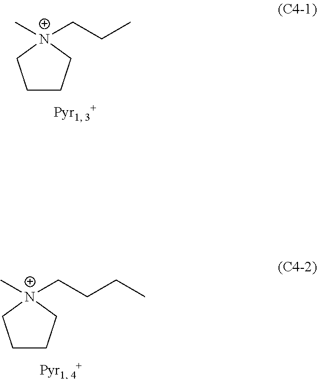

Examples of cations of the piperidinium type include Pip_{1,3}⁺ represented by a chemical formula (C5-1) and Pip_{1,4}⁺ represented by a chemical formula (C5-2), but are not limited to.

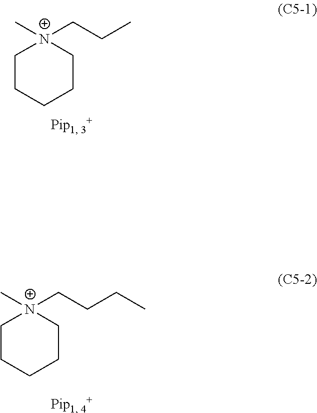

Examples of cations of the phosphonium type include P_{5,2,2,2}⁺ represented by a chemical formula (C6-1) and P_{6,6,6,14}⁺ represented by a chemical formula (C6-2), but are not limited thereto.

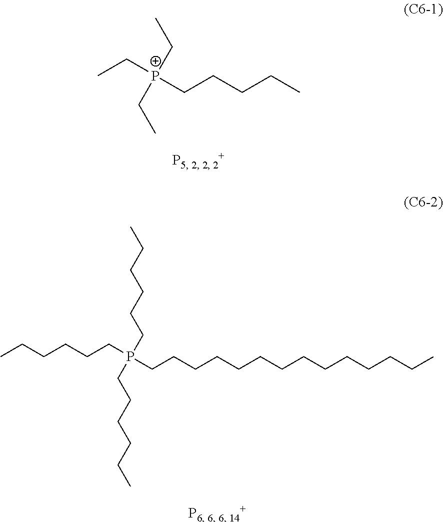

Examples of the anion constituting the ionic liquid include TfO-represented by a chemical formula (A1), Tf₂N⁻ (TFSA⁻) represented by a chemical formula (A2), Tf₃C⁻ represented by a chemical formula (A3), FSA-represented by a chemical formula (A4), CH₃COO⁻ represented by a chemical formula (A5), CF₃COO⁻ represented by a chemical formula (A6), BF₄⁻ represented by a chemical formula (A7), PF₆⁻ represented by a chemical formula (A8), (CN)₂N⁻ represented by a chemical formula (A9), AlCl₄⁻ represented by a chemical formula (A10), and Al₂Cl₇⁻ represented by a chemical formula (A11), but are not limited thereto.

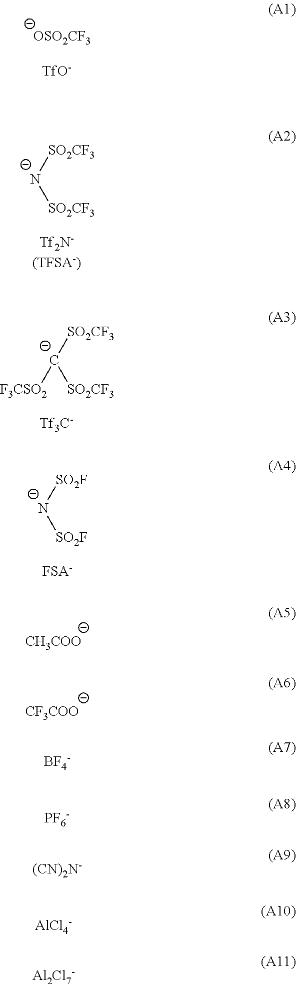

Specific examples of the ionic liquid include tributylhexadecylphosphonium 3-(trimethylsilyl)-1-propanesulfonate (BHDP·DSS) and N,N-diethyl-N-methyl-N(2-methoxyethyl) ammonium tetrafluoroborate (DEME·BF₄).

Examples of the ionic liquid used for the slurry in the case of serving as an oxidizing agent include those containing 2-iodoxybenzoic acid (IBX). Examples of the ionic liquid containing IBX include those represented by a chemical formula (B1).

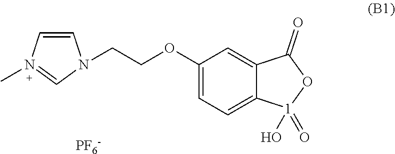

Examples of the ionic liquid used for the slurry in the case of serving as a corrosion inhibitor include those containing benzotriazole (BTA). Examples of the ionic liquid containing BTA include those represented by a chemical formula (B2).

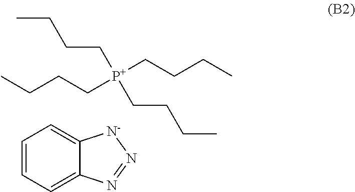 [SMILES: CCCC[P+](CCCC)(CCCC)CCCC ; c1ccc2[n-]nnc2c1]

The ionic liquid used in the slurry may contain abrasive grains. The abrasive grains function to achieve mechanical planarization. Examples of the type of abrasive grains include oxides, sulfides, and others. The abrasive grains may be a composite material of oxides, sulfides, and others. The abrasive grains having a grain size of 200 nm or less are used. Examples of the abrasive grains of oxides include SiO₂, CeO₂, Al₂O₃, ZrO₂, MnO₂, Mn₂O₃, SnO₂, TiO₂, Cr₂O, Fe₂O₃, NiO, and ZnO. Examples of the abrasive grains of sulfides include FeS and CuS. Examples of other abrasive grains include B₄C, diamond, c-BN, SiC, polymer abrasive grains, ionic liquid crystal in which the ionic liquid has a liquid crystal structure, and ionic crystal in which the ionic liquid has become solid. When a fixed abrasive grain pad or a semi-fixed abrasive grain pad containing these abrasive grains is used for the pad 52, the abrasive grains may not be contained in the slurry.

### Substrate Polishing Method

Next, a substrate polishing method according to the first embodiment will be described. FIG. 4 is a flowchart illustrating an example of the substrate polishing method according to the first embodiment.

The control device 11 controls the exhaust mechanism 30 to control the pressure in the chamber 20 to a predetermined pressure (for example, 10⁻⁵ Pa). The vacuum atmosphere in the present embodiment includes an atmosphere having a pressure lower than normal atmospheric pressure. The control device 11 opens the opening 22 by controlling the gate valve 23. When the opening 22 is opened, the substrate W is transferred into the processing space of the chamber 20 through the opening 22 and is held by the substrate holding unit 61. That is, the control device 11 controls the polishing apparatus 10 so as to hold the substrate W in the substrate holding unit 61 which is in the chamber 20 (step S1). The control device 11 closes the opening 22 by controlling the gate valve 23. The outside of the opening 22 is connected to the VTM 3 held at the same pressure (vacuum atmosphere) as in the chamber 20.

The control device 11 controls the slurry supply unit 70 to start supplying the slurry onto the pad 52. The control device 11 controls the pressurizing head unit 60 to pressurize the pressurizing head unit 60 so that the substrate W and the pad 52 are in contact with each other. In addition, the control device 11 polishes the substrate W by rotating the substrate W and the pad 52 by controlling the rotation stage 50 and the pressurizing head unit 60 (step S2). At the time of polishing, the control device 11 may control the slurry supply unit 70 to first supply a slurry containing an oxidizing agent to form an oxide film on the substrate W, and then switch to a slurry containing no oxidizing agent to remove the formed oxide film. In addition, the control device 11 may remove the formed oxide film or nitride film after oxidizing or nitriding the surface of the substrate W by supplying an oxygen-containing gas, a water-containing gas, or a nitrogen-containing gas into the chamber 20 through controlling a processing gas supply mechanism which is not illustrated. Furthermore, the control device 11 may electropolish the substrate W using an ionic liquid (slurry) between the substrate W and the pad 52 as an electrolyte by controlling a power supply which is not illustrated.

The control device 11 receives a measurement value changed by polishing the substrate W from the quadrupole mass spectrometer 40. The control device 11 detects the processing end point of the substrate W based on the input measurement value. Note that the control device 11 may detect the processing end point of the substrate W on the basis of various measurement values such as the torque of the rotation stage 50 or the pressurizing head unit 60, the reflectance of the surface of the substrate W, and the electric resistance via the ionic liquid between the rotation stage 50 and the pressurizing head unit 60. In addition, the control device 11 may supply the ionic liquid containing the corrosion inhibitor onto the pad 52 by controlling the slurry supply unit 70 after detecting the processing end point of the substrate W.

When detecting the processing end point of the substrate W, the control device 11 controls the slurry supply unit 70 to stop the supply of the slurry and controls the cleaning liquid supply unit 80 to start the supply of the cleaning liquid. The control device 11 cleans the substrate W by rotating the substrate W and the pad 52 by controlling the rotation stage 50 and the pressurizing head unit 60 (step S3). After controlling the cleaning liquid supply unit 80 to stop the supply of the cleaning liquid, the control device 11 controls the pressurizing head unit 60 to separate the substrate W from the pad 52, and removes the remaining slurry and cleaning liquid through spin drying of the substrate holding unit 61. After controlling the cleaning liquid supply unit 80 to stop the supply of the cleaning liquid, the control device 11 may control a heater which is not illustrated to increase the temperature of the substrate W to lower the viscosity of the cleaning liquid, and then perform spin drying. When the surface to be polished of the substrate W faces upward as in a polishing apparatus 210 described later, the control device 11 may control the cleaning liquid supply unit 80 to stop the supply of the cleaning liquid, then supply another ionic liquid having good wettability, replace the cleaning liquid with the ionic liquid, and then perform spin drying.

When cleaning and drying of the substrate W are completed, the control device 11 opens the opening 22 by controlling the gate valve 23. When the opening 22 is opened, the substrate W is transferred out from inside the chamber 20 by the robot arm 12 of the VTM 3 through the opening 22. That is, the control device 11 controls the substrate processing apparatus 1 so as to transfer out the substrate W held by the substrate holding unit 61 from inside the chamber 20 (step S4). The substrate W that has been transferred out is transferred to a next step such as to a plasma processing apparatus in a vacuum atmosphere while maintaining a vacuum state. As described above, the substrate W is polished in vacuum using the ionic liquid which is less likely to be volatilized in the vacuum atmosphere as the slurry, and thus, oxidation of the substrate W after polishing due to exposure to the atmosphere can be suppressed.

### Second Embodiment

In the first embodiment described above, the polishing apparatus 10 using the face down mechanism is used, but a polishing apparatus using a face up mechanism may also be used, and an embodiment in this case will be described as a second embodiment. In the polishing apparatus according to the second embodiment, the same components as those of the first embodiment are denoted by the same reference signs, and the description of the overlapping components and operations will be omitted.

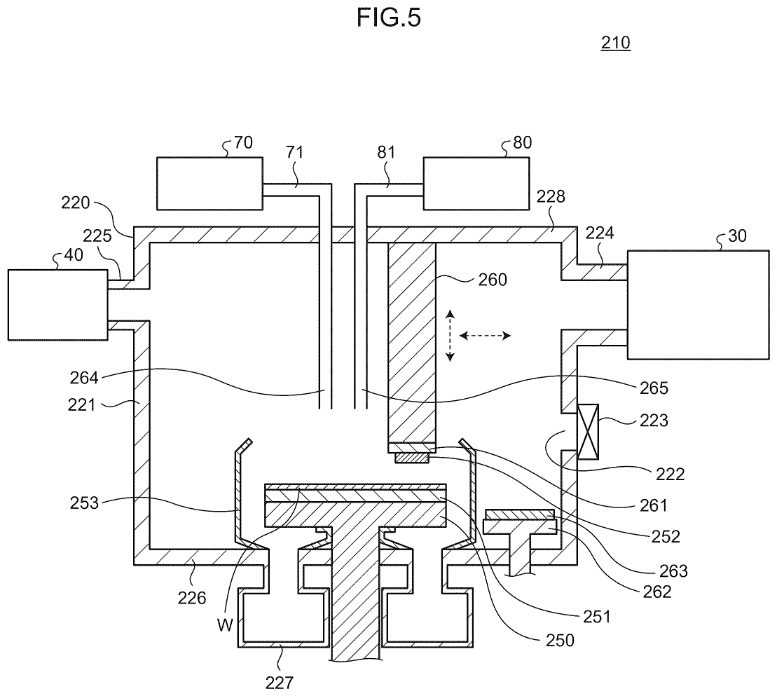

FIG. 5 is a schematic sectional view illustrating an example of the polishing apparatus according to the second embodiment. The polishing apparatus 210 illustrated in FIG. 5 is provided in the substrate processing apparatus 1 instead of the polishing apparatus 10 of the first embodiment. The polishing apparatus 210 includes a chamber 220, a rotation stage 250, and a pressurizing head unit 260 instead of the chamber 20, the rotation stage 50, and the pressurizing head unit 60 of the first embodiment. Each unit of the polishing apparatus 210 is controlled by the control device 11.

An opening 222 through which the substrate W passes is formed in a side wall 221 of the chamber 220, and the opening 222 is opened and closed by a gate valve 223. The exhaust mechanism 30 is connected to an upper portion of the side wall 221 via an exhaust port 224. Furthermore, the quadrupole mass spectrometer 40 is connected to an upper portion of the side wall 221 via a pipe 225. The rotation stage 250 is disposed substantially at the center of a bottom surface 226 of the chamber 220. In addition, a recovery tank 227 for recovering the slurry is connected to the periphery of the rotation stage 250 on the bottom surface 226. Furthermore, a pad dressing unit 262 is provided on the outer peripheral side of the recovery tank 227 of the bottom surface 226.

The pressurizing head unit 260 and pipes 264, 265 are provided on the inner side of an upper surface 228 of the chamber 220. The slurry supply unit 70 and the cleaning liquid supply unit 80 are disposed outside the upper surface 228 of the chamber 220. The chamber 220 is an example of a processing container.

The rotation stage 250 includes a substrate holding unit 251. The substrate holding unit 251 holds the substrate W to be processed and is disposed to face the pressurizing head unit 260. The substrate holding unit 251 holds the substrate W, for example, by a mounting surface having a recess on which the substrate W can be mounted, an electrostatic chuck, a mechanical chuck, or the surface tension of an ionic liquid contained in a backing material such as foamed urethane wetted with the ionic liquid. The rotation stage 250 can polish the substrate W to be processed by CMP, for example, by rotating at 10 rpm to 300 rpm. A recovery cup 253 for recovering slurry is provided around the rotation stage 250. Note that the recovery cup 253 is movable in the vertical direction by a drive mechanism, and when the substrate W is transferred in and out, the substrate W can be transferred in and out from the opening 222 by being moved in the downward direction.

The pressurizing head unit 260 includes a holding unit 261 that holds a pad and a pad 252 at a lower leading end. The pad 252 held by the holding unit 261 is disposed to face the rotation stage 250. The pad 252 is for polishing the substrate W, and can polish, for example, an area corresponding to the radius of the substrate W. Further, the substrate W may be polished by moving the pressurizing head unit 260 in the radial direction (the horizontal direction in FIG. 5) of the substrate W. A plurality of pressurizing head units 260 may be provided, and the substrate W may be polished by a plurality of pads 252. The pad 252 may be made of, for example, foamed urethane, nonwoven fabric composed of polyester fibers and urethane, suede, acrylic, Al₂O₃, or the like. As the pad 252, a fixed abrasive pad in which abrasive grains are embedded in the pad, or a semi-fixed abrasive pad in which abrasive grains are embedded in a mesh-like resin may be used. The pressurizing head unit 260 is movable in the vertical direction and the horizontal direction. The pressurizing head unit 260 pushes the pad 252 held by the holding unit 261 against the substrate W of the rotation stage 250, and for example, the rotation stage 250 and the pressurizing head unit 260 rotate at 10 rpm to 300 rpm, whereby the substrate W to be processed can be polished by CMP. That is, the substrate holding unit 251 is disposed such that the surface to be polished of the substrate W is the upper surface, the holding unit 261 is configured to hold the pad 252 such that the surface of the pad 252 is the lower surface, and the substrate W is polished in vacuum through pressurizing the pad 252 downward by the pressurizing head unit 260.

The pad dressing unit 262 has a grindstone 263 on the upper surface. The pad dressing unit 262 is rotatable, and the pad 252 of the pressurizing head unit 260 moved onto the grindstone 263 is pressed against the grindstone 263 to scrape the surface of the pad 252 and refresh the surface of the pad 252.

The slurry supply unit 70 is connected to the pipe 264 penetrating the upper surface 228 of the chamber 220 via the pipe 71. That is, in the chamber 220, a slurry which is an ionic liquid is dropped and supplied from the pipe 264 onto the substrate W. The slurry recovered by the recovery cup 253 is stored in the recovery tank 227 using gravity. The slurry stored in the recovery tank 227 may be circulated during a polishing step by, for example, a pump which is not illustrated and to which mechanical pressure can be applied.

The cleaning liquid supply unit 80 is connected to the pipe 265 penetrating the upper surface 228 of the chamber 220 via the pipe 81. That is, in the chamber 220, a cleaning liquid which is an ionic liquid is dropped and supplied from the pipe 265 onto the substrate W. The cleaning liquid recovered by the recovery cup 253 is stored in another recovery tank 227 different from the recovery tank 227 storing the slurry. That is, a valve which is not illustrated is provided at the inlet of the recovery tank 227, and the valve is controlled to switch between slurry recovery and cleaning liquid recovery so that the slurry and the cleaning liquid are recovered in different recovery tanks 227.

In the polishing apparatus 210, the substrate polishing method can be similarly performed in vacuum except that the position where the substrate W is held is different from the position of the polishing apparatus 10 of the first embodiment. As described above, the substrate W is also polished in the vacuum atmosphere in the polishing apparatus 210, and thus, oxidation of the substrate W after polishing due to exposure to the atmosphere can be suppressed.

In the second embodiment described above, the size of the pad 252 has been described as corresponding to the radius of the substrate W, but is not limited thereto. For example, the pad 252 may have a size capable of polishing the entire surface of the substrate W, that is, a size equal to or greater than the diameter of the substrate W. In this case, the pipes 264, 265 may be connected to a showerhead-shaped flow path provided inside the pad 252, and the slurry and the cleaning liquid may be introduced from the flow path to the surface of the substrate W. Thus, the surface of the substrate W can be polished with improved flatness compared to the case of the second embodiment.

As described above, according to each embodiment, the polishing apparatuses 10, 210 each include the processing container (chamber 20), the substrate holding unit (the substrate holding units 61, 251), the pad holding unit (the holding units 51, 261), the slurry supply unit 70, and the pressurizing head units 60, 260. The processing container provides a processing space in a vacuum atmosphere. The substrate holding unit is disposed in the processing container and holds the substrate W to be processed. The pad holding unit is disposed to face the substrate holding unit and holds the pads 52, 252 for polishing the substrate W. The slurry supply unit 70 supplies the slurry which is the ionic liquid to the surface of the substrate W or the pad 52. The pressurizing head units 60, 260 pressurize the substrate holding unit or the pad holding unit. In addition, one of the substrate holding unit and the pad holding unit is pressurized such that the substrate W and the pads 52, 252 are in contact with each other, and the substrate W and the pads 52, 252 are relatively rotated in a state where the slurry is supplied. As a result, the substrate surface after polishing is advanced to the next step without being exposed to the atmosphere, and thus, oxidation of the substrate after polishing can be suppressed.

In addition, according to each embodiment, the slurry supply unit 70 supplies the slurry by applying mechanical pressure. As a result, the slurry can be supplied even when the inside of the chamber 20 is in a vacuum atmosphere.

Further, according to each embodiment, the slurry supply unit 70 supplies the slurry by a diaphragm type pump, a tubing type pump, or a capacity calculation type pump. As a result, the slurry can be supplied even when the inside of the chamber 20 is in a vacuum atmosphere.

In addition, according to each embodiment, the polishing apparatuses 10, 210 each further include a discharge unit that is connected to the slurry supply unit 70 and discharges the slurry onto the surface of the substrate W or the pads 52, 252. The discharge unit is a syringe including a needle valve or a stop valve, or a slit. As a result, the slurry can be supplied to the surface of the substrate W or the pads 52, 252 even when the inside of the chamber 20 is in a vacuum atmosphere.

Further, according to each embodiment, the substrate holding unit holds the substrate W by an electrostatic chuck, a mechanical chuck, or the surface tension of an ionic liquid contained in a backing material such as foamed urethane wetted with the ionic liquid. As a result, the substrate W can be held even when the inside of the chamber 20 is in a vacuum atmosphere.

In addition, according to each embodiment, the slurry contains abrasive grains. As a result, the substrate W can be mechanically polished and planarized.

In addition, according to each embodiment, the pads 52, 252 each include abrasive grains. As a result, the substrate W can be mechanically polished and planarized.

According to each embodiment, the polishing apparatuses 10, 210 each further include the cleaning liquid supply unit 80 configured to supply the cleaning liquid which is the ionic liquid to the surface of the substrate W or the pad 52. The substrate holding unit removes the slurry and the cleaning liquid by spin drying. As a result, the surface of the substrate W after polishing can be kept clean.

According to the first embodiment, the pad holding unit is disposed such that the surface of the pad 52 is the upper surface. In addition, the substrate holding unit is configured to hold the substrate W such that the surface to be polished of the substrate W is the lower surface, and is pressurized downward by the pressurizing head unit 60. As a result, the parallelism of the surface of the substrate W can be further improved.

In addition, according to each embodiment, the polishing apparatuses 10, 210 respectively further include the recovery cups 53, 253 which are configured to surround the pad holding unit or the substrate holding unit and recover the slurry. As a result, the slurry can be reused.

According to the second embodiment, the substrate holding unit 251 is disposed such that the surface to be polished of the substrate W is the upper surface. The pad holding unit is configured to hold the pad 252 such that the surface of the pad 252 is the lower surface, and is pressurized downward by the pressurizing head unit 260. As a result, the polishing apparatus 210 can be downsized.

It should be understood that the embodiments disclosed herein are illustrative in all respects and not restrictive. Each of the above embodiments may be omitted, replaced, or modified in various aspects without departing from the scope and spirit of the appended claims.

In each of the above embodiments, spin drying is performed after cleaning of the substrate W, but the present invention is not limited thereto. For example, when abrasive grains are not used, the substrate W may be transferred to a plasma processing apparatus in a vacuum atmosphere, and an ionic liquid such as a cleaning liquid may be removed by dry etching such as hydrogen plasma. In addition, for example, an ionic liquid such as a cleaning liquid remaining on the surface of the substrate W may be removed using a brush which is not illustrated. Further, for example, blowing using a differential pressure may be performed with a small amount of nitrogen-containing gas using a nozzle which is not illustrated.

In each of the above embodiments, the substrate W is transferred into each of the polishing apparatuses 10, 210 from the VTM 3 in the vacuum atmosphere, but the present invention is not limited thereto. For example, the substrate W may be transferred into each of the polishing apparatuses 10, 210 from a transfer chamber in an atmospheric atmosphere, and the polishing step may be performed after the pressure of the transfer chamber is reduced to a vacuum atmosphere after the substrate W is transferred in.

Note that the present disclosure can also have the following configurations.

(1)
A polishing apparatus comprising:
a processing container that is configured to provide a processing space in a vacuum atmosphere;
a substrate holding unit that is configured to be disposed in the processing container and hold a substrate to be processed;
a pad holding unit that is configured to be disposed to face the substrate holding unit and hold a pad for polishing the substrate;
a slurry supply unit that is configured to supply a slurry which is an ionic liquid to a surface of the substrate or the pad; and
a pressurizing head unit that is configured to pressurize the substrate holding unit or the pad holding unit, wherein
one of the substrate holding unit and the pad holding unit is pressurized such that the substrate and the pad are in contact with each other, and the substrate and the pad are relatively rotated in a state where the slurry is supplied.
   (2)

The polishing apparatus according to (1), wherein
the slurry supply unit supplies the slurry by applying a mechanical pressure.
   (3)

The polishing apparatus according to (2), wherein
the slurry supply unit supplies the slurry by a diaphragm type pump, a tubing type pump, or a capacity calculation type pump.
   (4)

The polishing apparatus according to (3), further comprising:
a discharge unit that is connected to the slurry supply unit and discharges the slurry onto a surface of the substrate or the pad, wherein
the discharge unit is a syringe including a needle valve or a stop valve, or a slit.
   (5)

The polishing apparatus according to any one of (1) to (4), wherein
the substrate holding unit holds the substrate by an electrostatic chuck, a mechanical chuck, or surface tension of the ionic liquid.
   (6)

The polishing apparatus according to any one of (1) to (5), wherein
the slurry contains an abrasive grain.
   (7)

The polishing apparatus according to any one of (1) to (5), wherein
the pad contains an abrasive grain.
   (8)

The polishing apparatus according to any one of (1) to (7), further comprising:
a cleaning liquid supply unit that is configured to supply a cleaning liquid, which is an ionic liquid, to a surface of the substrate or the pad, wherein
the substrate holding unit removes the slurry and the cleaning liquid by spin drying.
   (9)

The polishing apparatus according to any one of (1) to (8), wherein
the pad holding unit is disposed such that a surface of the pad is an upper surface, and
the substrate holding unit is configured to hold the substrate such that a surface to be polished of the substrate is a lower surface, and is pressurized downward by the pressurizing head unit.
   (10)

The polishing apparatus according to (9), further comprising:
a recovery cup that is configured to surround the pad holding unit and recovers the slurry.
   (11)

The polishing apparatus according to any one of (1) to (8), wherein
the substrate holding unit is disposed such that a surface to be polished of the substrate is an upper surface, and
the pad holding unit is configured to hold the pad such that a surface of the pad is a lower surface, and is pressurized downward by the pressurizing head unit.
   (12)

The polishing apparatus according to (11), further comprising:
a recovery cup that is configured to surround the substrate holding unit and recovers the slurry.
   (13)

A substrate polishing method comprising:
a step of holding a substrate to be processed in a substrate holding unit which is disposed in a processing container and holds the substrate;
a step of pressurizing the substrate holding unit or a pad holding unit which is arranged to face the substrate holding unit such that the substrate and a pad which is for polishing the substrate and is held by the pad holding unit are in contact with each other, supplying a slurry which is an ionic liquid to a surface of the substrate or the pad, and relatively rotating the substrate and the pad to polish the substrate in a vacuum;
a step of detecting a processing end point of the substrate based on a measurement value changed by polishing the substrate;
a step of supplying a cleaning liquid which is an ionic liquid to a surface of the substrate or the pad, and removing the slurry and the cleaning liquid by spin drying of the substrate holding unit; and
a step of transferring out the substrate held by the substrate holding unit from the processing container.

According to the present disclosure, unintended oxidation of a substrate surface after polishing can be suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A polishing apparatus comprising:
a processing container that is configured to provide a processing space in a vacuum atmosphere;
a substrate holding unit that is configured to be disposed in the processing container and hold a substrate to be processed;
a pad holding unit that is configured to be disposed to face the substrate holding unit and hold a pad for polishing the substrate;
a slurry supply unit that is configured to supply a slurry which is an ionic liquid to a surface of the substrate or the pad; and
a pressurizing head unit that is configured to pressurize the substrate holding unit or the pad holding unit, wherein
one of the substrate holding unit and the pad holding unit is pressurized such that the substrate and the pad are in contact with each other, and the substrate and the pad are relatively rotated in a state where the slurry is supplied.

2. The polishing apparatus according to claim 1, wherein
the slurry supply unit supplies the slurry by applying a mechanical pressure.

3. The polishing apparatus according to claim 2, wherein
the slurry supply unit supplies the slurry by a diaphragm type pump, a tubing type pump, or a capacity calculation type pump.

4. The polishing apparatus according to claim 3, further comprising:
a discharge unit that is connected to the slurry supply unit and discharges the slurry onto a surface of the substrate or the pad, wherein
the discharge unit is a syringe including a needle valve or a stop valve, or a slit.

5. The polishing apparatus according to claim 1, wherein
the substrate holding unit holds the substrate by an electrostatic chuck, a mechanical chuck, or surface tension of the ionic liquid.

6. The polishing apparatus according to claim 1, wherein
the slurry contains an abrasive grain.

7. The polishing apparatus according to claim 1, wherein
the pad contains an abrasive grain.

8. The polishing apparatus according to claim 1, further comprising:
a cleaning liquid supply unit that is configured to supply a cleaning liquid, which is an ionic liquid, to a surface of the substrate or the pad, wherein
the substrate holding unit removes the slurry and the cleaning liquid by spin drying.

9. The polishing apparatus according to claim 1, wherein
the pad holding unit is disposed such that a surface of the pad is an upper surface, and
the substrate holding unit is configured to hold the substrate such that a surface to be polished of the substrate is a lower surface, and is pressurized downward by the pressurizing head unit.

10. The polishing apparatus according to claim 9, further comprising:
a recovery cup that is configured to surround the pad holding unit and recovers the slurry.

11. The polishing apparatus according to claim 1, wherein
the substrate holding unit is disposed such that a surface to be polished of the substrate is an upper surface, and
the pad holding unit is configured to hold the pad such that a surface of the pad is a lower surface, and is pressurized downward by the pressurizing head unit.

12. The polishing apparatus according to claim 11, further comprising:
a recovery cup that is configured to surround the substrate holding unit and recovers the slurry.

13. A substrate polishing method comprising:
a step of holding a substrate to be processed in a substrate holding unit which is disposed in a processing container and holds the substrate;
a step of pressurizing the substrate holding unit or a pad holding unit which is arranged to face the substrate holding unit such that the substrate and a pad which is for polishing the substrate and is held by the pad holding unit are in contact with each other, supplying a slurry which is an ionic liquid to a surface of the substrate or the pad, and relatively rotating the substrate and the pad to polish the substrate in a vacuum;
a step of detecting a processing end point of the substrate based on a measurement value changed by polishing the substrate;
a step of supplying a cleaning liquid which is an ionic liquid to a surface of the substrate or the pad, and removing the slurry and the cleaning liquid by spin drying of the substrate holding unit; and
a step of transferring out the substrate held by the substrate holding unit from the processing container.
